(19) United States
(12) Patent Application Publication
(10) Pub. No.: US 2011/0037455 A1
(43) Pub. Date: Feb. 17, 2011

(54) SYSTEM FOR MEASURING ELECTRICAL POWER

(76) Inventors: Navot OREN, Ramat-Efal (IL); Eyal Gabay, Kfar-Saba (IL)

Correspondence Address: SOROKER-AGMON ADVOCATE AND PATENT ATTORNEYS, NOLTON HOUSE, 14 SHENKAR STREET, HERZELIYA PITUACH, 46725, IL

(21) Appl. No.: 12/541,990

(22) Filed: Aug. 17, 2009

(51) Int. Cl. G01R 11/00

(52) U.S. Cl. 324/103 R

(57) ABSTRACT

The claimed subject matter discloses a system for measuring power consumption of an electrical appliance. The system comprises a sensing module for sensing physical phenomenon, located externally to the electrical appliance. The system further comprises a transmitter for transmitting information representing the physical phenomenon sensed by the sensing module and a power device. The physical phenomenon sensed by the sensing module provides indication on whether the electrical appliance is ON or OFF and whether the power consumption of the electrical appliance increased or decreased. In some cases, the indication is one or more scalars representing the sensed physical phenomena.

### BACKGROUND OF THE INVENTION

1. Technical Field

The present disclosure relates to measuring electrical power in general, and to measuring electrical power of electrical appliances in particular.

2. Discussion of the Related Art

Power consumption of electrical appliances has much influence of human lives. For example, it affects resource consumption of substances used for producing electrical power, such as coal. Reducing power results in less pollution, less coal required for electrical power and other consequences. Electrical power companies try to reduce the maximal power consumption by controlling loads, provide different prices for peak hours and the like.

Many systems for measuring electrical power consumption are used and marketed for analyzing power consumption and create patterns or reports that can be used in reducing power consumption. Researches show that feedback to the consumer may result in reducing the power consumption in general and particularly during the peak demand periods, and may prevent establishment of new and unnecessary power plants.

Some power consumption measuring systems use power meter for every electrical appliance and are therefore costly since they require safety mechanisms, accuracy and in most cases also interface to AC voltage. Other systems send power consumption from the electrical appliance itself, and require preprogrammed, smart electrical appliances or complex appliances, or modifying appliances to fit such systems.

Some of the drawbacks of known systems are incapability to measure power consumption of appliances that are not connected directly to sockets such as for example light bulbs and the need to interfere or stop the electrical appliance when installing the measuring unit. An apparatus connected to the outlet decreases reliability since it adds a potential failure point to the electricity current path towards the appliance.

A system and process for non-intrusively measuring power consumption of electrical appliances is hence a long felt need.

### SUMMARY OF THE PRESENT INVENTION

It is another object of the subject matter to disclose a system for measuring power consumption of an electrical appliance, the system comprises a sensing module for sensing physical phenomenon related to the power consumption of the electrical appliance, said sensing module is located externally to the electrical appliance. The system further comprises a transmitter for transmitting information related to the power consumption of the electrical appliance, said information represents the physical phenomenon sensed by the sensing module and a power device.

In some embodiments, the physical phenomenon sensed by the sensing module provides indication on whether the electrical appliance is ON or OFF. In some embodiments, the physical phenomenon sensed by the sensing module provides an indication on whether the power consumption of the electrical appliance increased or decreased.

In some embodiments, the indication comprises one or more scalar values indicating change in the magnitude of the sensed information. In some embodiments, the indication comprises one or more scalar values indicating the magnitude of the sensed information.

In some embodiments, the sensing module senses a magnetic field adjacent and external to the power cable transferring power to the electrical appliance. In some embodiments, the system further comprises a processing unit for determining the information transmitted by the transmitter according to the sensed physical phenomenon.

In some embodiments, the sensing module enables sensing the physical phenomenon without opening the power cable or connecting an intermediate apparatus located between the electrical outlet and the power outlet associated with the electrical appliance. In some embodiments, the sensing module enables sensing the physical phenomenon without inducing a predefined current into an electrical conductor within the power cable. The physical phenomenon may be selected from a group consisting of heat, light, noise, motion, rotation speed or a combination thereof.

In some embodiments, the system of claim 1, further comprises a clamping device for attaching the sensing module to the power cable transferring power to the electrical appliance, said power cable contains two or more electrical conductors. In such case, the sensing module senses the magnetic field magnitude externally to the power cable, and the sensing module is positioned in a location in which the magnetic field magnitudes of the two or more electrical conductors do not balance each other.

It is another object of the subject matter to disclose a system for determining power consumption of an electrical appliance. The system comprises a first receiving unit for receiving information from a sensing module located externally to the electrical appliance and a second receiving unit for receiving information from a power meter that stores power consumption of a plurality of electrical appliances. At least one of the plurality of electrical appliances is associated with a sensing module that sends information representing the physical phenomenon sensed by the sensing module and transmitted to the first receiving device. The system also comprises a processor for determining the power consumption of the electrical appliance as a function of the information received at the first receiving unit and at the second receiving unit.

In some embodiments, the system further comprises a pattern unit for storing power consumption of electrical appliances in specific times and determines the pattern of the power consumption of specific electrical appliances in specific time frames.

In some embodiments, the system further comprises a malfunction/abnormal behavior detection unit that compares the power consumption determined by the processor and the pattern stored in the pattern unit to determine whether the consumption is valid or invalid.

It is another object of the subject matter to disclose a method of measuring power consumption of electrical appliances, the method comprises receiving information from a power meter that stores power consumption of a plurality of electrical appliances and receiving an indication from a sensing apparatus associated with an electrical appliance of the plurality of electrical appliances. Said indication provides information representing physical phenomenon sensed by a sensing module located externally to the electrical appliance and externally to the power cable transferring power to the electrical appliance. The method further provides for determining the power consumption of the electrical appliance as a function of the information received from the power meter and the information received from the sensing apparatus.

In some embodiments, the indication is limited to whether the electrical appliance is ON or OFF and whether the power consumption of the electrical appliance increased or decreased. In some embodiments, the indication is a scalar, which is a function of the data, sensed externally to the power cable and externally to the electrical appliance.

In some embodiments, the method further comprises a step of calculating a factor between the scalar received from a specific electrical appliance and the difference in power consumption of the same electrical appliance. In some embodiments, the method further comprises a step of determining the power consumption of the electrical appliance using the factor.

### BRIEF DESCRIPTION OF THE DRAWINGS

Exemplary non-limited embodiments of the disclosed subject matter will be described, with reference to the following description of the embodiments, in conjunction with the figures. The figures are generally not shown to scale and any sizes are only meant to be exemplary and not necessarily limiting. Corresponding or like elements are designated by the same numerals or letters.

FIG. 1 schematically illustrates an electrical environment of measuring power consumption, in accordance with an exemplary embodiment of the disclosed subject matter,

FIG. 2 shows a central unit for measuring power consumption, according to some exemplary embodiments of the disclosed subject matter;

FIG. 3 shows a flow of measuring power consumption of specific electrical appliances, according to some exemplary embodiments of the disclosed subject matter;

FIG. 4 shows the connection of the sensing apparatus to the power cable in the exemplary embodiment where the sensing apparatus measures the magnetic field adjacent to the power cable connected to the associate electrical appliance.

### DETAILED DESCRIPTION OF THE PREFERRED EMBODIMENT

The technical problem dealt with in the disclosed subject matter is to measure the power consumption of electrical appliances (EA) without modifying the appliances and without any interruption to the appliance or the power cable transferring power to the electrical appliance. Modifying may relate to shutting off the electrical appliance when installing a measuring sensor, changing the electricity-wiring infrastructure, adding a potential failure point in the electricity current path towards the appliance and the like. Another technical problem is to measure the power consumption without intruding into the EA after manufactured.

One technical solution suggested in the subject matter is a sensing apparatus comprising a sensing module located externally to the EA for sensing data concerning the power consumption of the EA. Such information may be whether the EA is active or passive, whether the power consumption increases or decreases and the like. The sensing module may detect or measure a magnetic field near the power cable that contains the electrical conductors that transfer power to the EA. The sensing module may also detect another physical phenomenon such as heat, light, noise and the like. The sensing apparatus may further comprise a transmitter for transmitting the sensed information or another value that is a function of the sensed information to a central unit. Such central unit determines the power consumption of a specific EA according to the indication from the sensing apparatus and according to exact measurements of the source, which provides the power to the specific EA and optionally to more appliances.

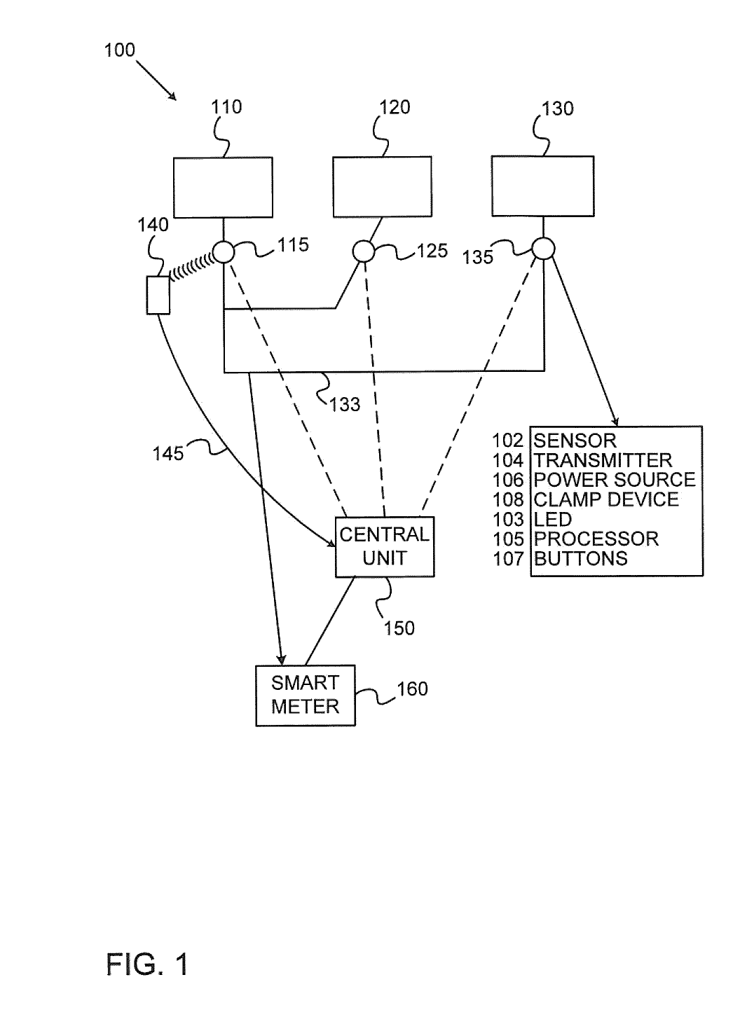

FIG. 1 schematically illustrates an electrical environment of measuring power consumption, in accordance with an exemplary embodiment of the disclosed subject matter. The electrical environment 100 comprises electrical appliances (EAs) 110, 120 and 130. At least one of the EAs 110, 120, 130 is associated to sensing apparatus. For example, EA 110 is associated to sensing apparatus 115, EA 120 is associated to sensing apparatus 125 and EA 130 is associated to sensing apparatus 135. The EAs 110, 120, 130 may be connected to a wall plug or wall socket, such as for example a refrigerator, a television set and a washing machine. Alternatively, the EA may be connected directly to the power line, such as light bulbs. Alternatively, the EA may be connected to power lines via another EA, as used in some monitors connected solely to a computer from which the data displayed on the monitor is provided.

The sensing apparatuses 115, 125 and 135 are not integral to the EA 110, 120 and 130, such that said sensing apparatuses 115, 125 and 135 can be located externally to EAs 110, 120 and 130. In some exemplary embodiments of the disclosed subject matter, the sensing apparatus 135 comprises a sensing module 102. Such sensing module 102 of the sensing apparatus 135 may sense a magnetic field near the electrical conductor of the EA 130. For example, the sensing module 102 can reside anywhere along the electrical conductor of EA 130. In some exemplary embodiments of the disclosed subject matter, measuring the magnetic field along the power cord of the EA 130 is performed using the Faraday law. This is done by using a coil to detect the magnetic field created near the electrical conductor, when the EA 130 is operated. In some embodiments, detecting and measuring the magnetic field may be performed using Hall Effect or other methods desired by a person skilled in the art.

The sensing module 102 provides a general indication. For example, indicates whether the EA operates, and indication as to whether the power consumption decreases or increases, and the like. An indication concerning increase or decrease, and whether the EA operates or not may also be named HOLO (High, On, Low, Off). In some other cases, the indication from the sensing apparatus may provide one or more scalar values according to the measured value. The central unit 150 may use such scalar value to determine the power consumption of the EA. In some cases, more than one scalar value is sent for one measurement sensed by the sensing module 102.

In some exemplary embodiments of the disclosed subject matter, the sensing module such as 102 senses other physical characteristics, such as temperature, light, motion, and the like. As such, when a light bulb is ON, the amount or color of light in the bulb's surroundings increases and the sensing module 102 can determine that the bulb is ON. Such detection may be performed using a photodiode. Similarly, the sensing module may sense rotational speed of engines, thus determining whether there is a change in the power consumption of the EA 130 associated with the sensing apparatus 135. The indication provided by the sensing apparatus 135 is sent to a central unit 150 using a transmitter 104. The central unit 150 may also receive measurements from a power meter 160 that detects or stores the total power consumption of one or more EAs, at least one of which is associated with the sensing apparatuses such as 135 that transmit the sensed data or a function of the sensed data to the central unit 150. The central unit 150 can then determine the change in total power consumption and as a result determine the power consumption of the EA associated with the sensing apparatus 135.

The transmitter, such as for example transmitter 104 may be wireless, for example using a communication protocol such as ZigBee, Z-Wave, WiFi Low Power, Bluetooth LE or another protocol desired by a person skilled in the art. In some cases, the transmitter transmits data-directly to the central unit 150. In some other cases, the transmitter 104 transmits data to an intermediate communication entity such as a transponder that transmits the data to the central unit 150. In some cases, the communication between the transmitter 104 of the sensing apparatus 135 to the intermediate entity 140 is wireless, and the communication between the intermediate entity 140 to the central unit 150 is wired. In other cases, communication between the intermediate entity 140 and the central unit 150 is also performed wirelessly.

The central unit 150 is connected to a power meter 160 that meters the actual sum of power consumption of electrical appliances connected to said power meter 160. The communication between the power meter 160 and the central unit 150 may be wired or wireless.

The power meter 160 may be a commercially available smart meter that contains a transmitter and optionally a receiver for communication. The central unit 150 measures power consumption of a specific electrical appliance using data concerning the actual sum of power consumption received according to data provided by the power meter. The actual sum of power consumption is compared or analyzed in view of data received to the central unit 150 by the sensing apparatuses, such as 135.

In some exemplary embodiments of the disclosed subject matter, the data transmitted by the transmitter 104 of the sensing apparatus 135 is a function of difference in the electrical power consumption of the EA. For example, start of operation of the EA, change in power consumption and the like. The central unit 150 may determine exact power consumption of EAs. The central unit 150 receives indication that a specific EA requires or consumes electrical power and receives the change of total power measured by a power meter in substantially the same time. In some cases, the central unit 150 calculates the exact power consumption of an EA using the two indications and from the history of previous indications.

The sensing apparatus 135 may further comprise a power source 106 providing power to the sensing apparatus 135. The power source 106 may be a battery, operate on solar technology, and the like. The power source may be embedded in the sensing apparatus 135 or may be connected to the sensing apparatus 135 externally, as desired by the person skilled in the art.

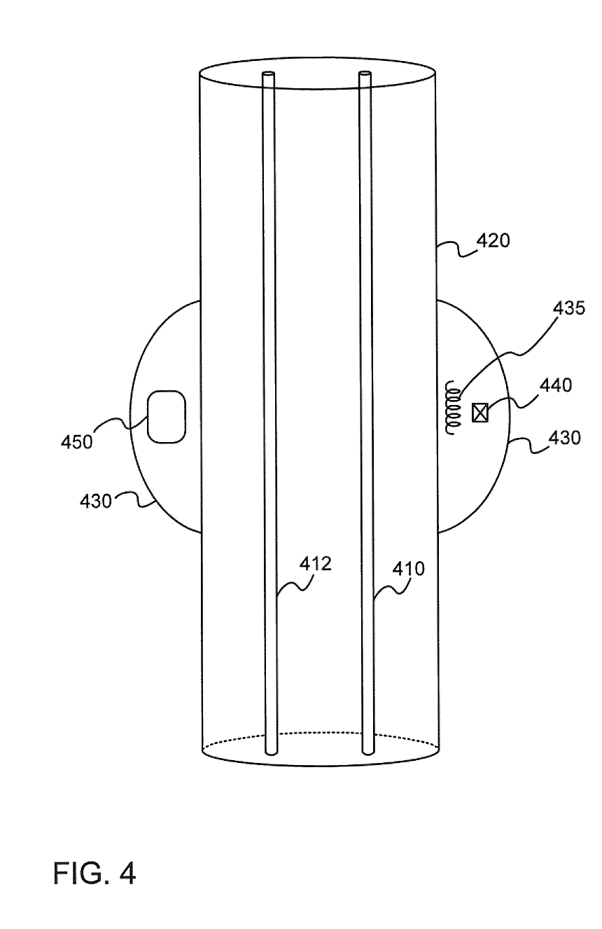

The sensing apparatus 135 may further comprise a clamp device 108 used to attach the sensing apparatus 135 to the power cable of the EA 130. In such exemplary embodiment, the sensing module 102 detects the magnetic field, which is associated with power consumption according to data sensed near and externally to the power cable that contains the electrical conductors without intruding into the power cable, as disclosed in FIG. 4. The clamp device 108 may be connected to a construction element, such as a wall or ceiling in a construction in or adjacent to the location of the EA. In such case, the clamp device 108 may use magnetic power, Velcro and the like. In such alternative embodiments, the clamp device may comprise mechanical tools to clamp the sensing apparatus 135 to the EA or to another module in the related environment, for example mechanical arms, wires, gripping mechanism and the like. For s example, the clamp device 108 may attach the sensing apparatus 135 to a ceiling adjacent to a light bulb. The sensing module 102 may then sense light or heat and the transmitter 104 will transmit information representing the indication of the light or heat to the central unit 150.

The sensing apparatus 135 may further comprise a processing unit 105 (not shown) for processing the sensed data before transmitted to the central unit 150. The processing unit 105 may be a basic controller that processes the measurement, prepares the data for transmission and responsible for indications such as a LED or another illumination device 103. The processing unit 105 may reside within or communicates with the sensing apparatus 135. Thus, for example, when the sensed data is a value, for example magnetic field amplitude, noise, light and the like, the processing unit 105 processes the value of the sensed value and send a scalar, or more than one scalar, that represents the result of arithmetic or logic representation of the measured values sensed by the sensing module 102.

The processing unit 105 may perform calculations and calibrations. For example, the processing unit 105 may calculate average of samples measured by the sensing module 102 within a predefined sliding window. The processing unit 105 may also perform analog to digital conversions.

The sensing apparatus 135 may also contain a button 107 to facilitate installation on the power cable. The buttons 107 may be used to reset the sensing apparatus and maybe other functionalities, such as clearing notification issued by the central unit 150 that relates to the electrical appliance 130.

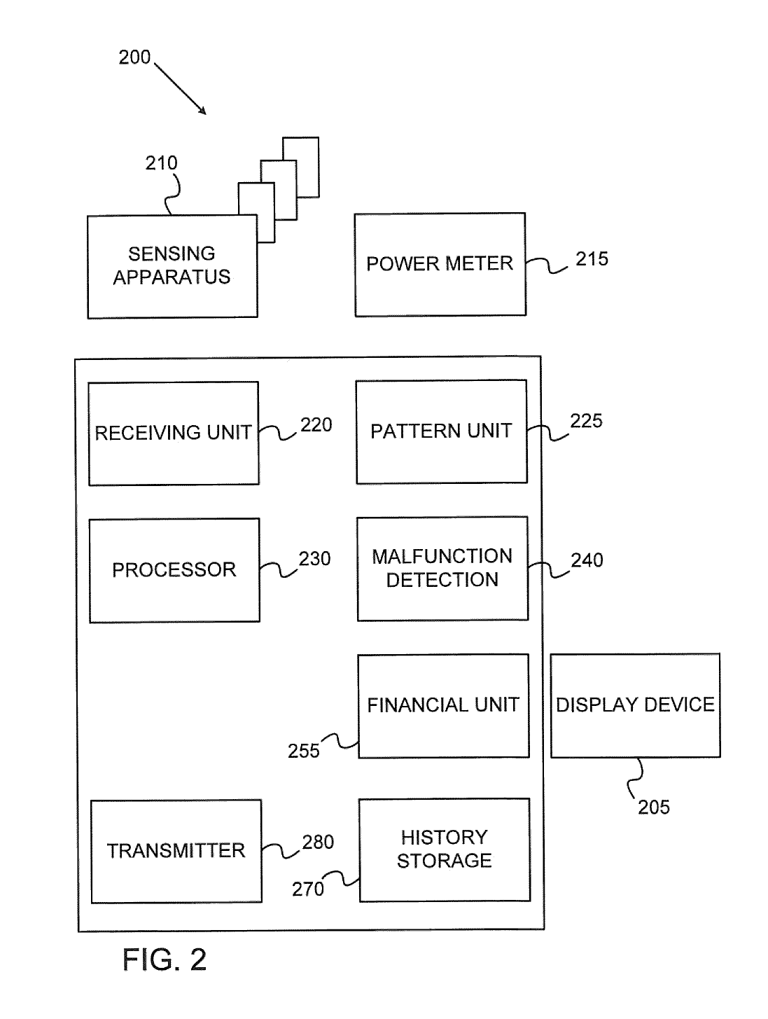

FIG. 2 shows a central unit for measuring power consumption, according to some exemplary embodiments of the disclosed subject matter. The central unit 200 is connected to a sensing apparatus 210, equivalent to 135 of FIG. 1, to receive indication as to whether the power consumption increased, decreased, whether the electrical appliance is ON, or OFF. Such indication may also be named as HOLO (High, ON, Low, OFF) indication. Other indications may comprise one or more scalar values used to calculate the exact power consumption of EAs. The central unit 200 may be connected to a plurality of sensing apparatuses and receive different indications from the plurality of sensing apparatuses. For example, each of the plurality of sensing apparatuses may be associated with another electrical appliance, each sensing apparatus may provide the sensed data differently, and the data may be represented differently.

The central unit 200 comprises a receiving unit 220 for receiving data from the sensing apparatus 210 and from a power meter 215 (equivalent to 160 in FIG. 1). Such data may be received into a port in the processing unit 200. The receiving unit 220 may receive data wirelessly, from a wired source, or both according to system specifications. The receiving unit 220 may associate the data source with an electrical appliance; for example, data received from source number five may be associated with a refrigerator. In some exemplary embodiments of the disclosed subject matter, the receiving unit 220 sends the received data to a processor 230 to analyze the received data. In some exemplary embodiments, the processor 230 performs association of data with an electrical appliance.

The processor 230 may operate hardware or software modules to analyze the data received from both the power meter 215 and the sensing apparatus 210. The processor 230 may contain a set of rules or algorithms used to analyze the received data. In some exemplary embodiments, the processor 230 determines the power consumption of a specific electrical appliance by receiving the time in which the electrical appliance was turned ON and the difference in the total power consumption in the period of time in which the electrical appliance was ON. The total power consumption may be received from the power meter 215. The total power consumption may refer to a group of electrical appliances measured by the same power meter, not necessarily to all the electrical appliances in the same construction. The processor 230 may also analyze the power consumption of electrical appliances as a function of High/Low indications, as to whether the power consumption of the electrical appliance increases or decreases. For example, the processor 230 receives indications from the power meter 215 via the receiving unit 220 that the total power consumption of the EAs associated with the specific power meter increased. The processor also receives a High indication, indicating increase in power consumption, from the sensing apparatus associated with an EA connected to the same power meter 215, the processor associates the increase in power consumption to the specific EA.

The processor 230 may perform some commands or implement a set of rules on the received data. For example, once the processor 230 receives a HOLO indication, it runs a set of rules or commands that computes an updated power value for the EA associated with the sensing apparatus that sent the HOLO indication. For example, in FIG. 1, there are three EAs connected to the same power source and three sensing apparatuses, each adjacent to an EA, and the power meter 160. In case the power meter 160 sends a new power measurement that is 400 watts higher than the previous power measurement, and in case the only data received after the previous total power measurement was an ON indication from the sensing apparatus 115 associated with EA 110, the algorithm defines that EA 110 consumes 400 watts.

In case the sensing apparatus 115 comprises a linear sensor that is capable of sending a scalar, the processor 230 also uses the computed power consumption and the scalar to calibrate the sensor as described below. In some cases, there are two or more scalars for the same measurement, one provides the measured value and the other provides the difference from the previous measurement.

Some sensor apparatuses comprise sensing modules 102 that provide a value related to the physical phenomena they measure. For example, measuring magnetic field can produce a scalar value of 5 for low magnetic field and 200 for higher magnetic fields. These values may be in the range of digital samples that the sensing module 102 provides. The scalar is transmitted with the HOLO indication from the sensing apparatus 135 to the central unit 200. The processor 230 calculates the relation factor between the scalar and the power consumption. The scalar may be digital sample converted from the measured value. The Factor is computed separately per EA. The factor may be calculated as a function of the formula:

EA Power Consumption/Scalar.

For example, in case the sensing apparatus 135 sends a scalar value of 10, the Factor will be Factor=Power consumption/scalar=400/10=40. In some cases, the Factor is monitored continuously. The Factor may also be calculated as a function of the formula: Power Consumption Diff/scalar Diff, which refers to the differences between previous measurements. In such cases, the Factor is updated and its accuracy is improved every time a new relevant measurement is received.

In another example, more than one sensing apparatus sends indication at the same time. For example, two HIGH indications are sent at the same time from sensing apparatus 115 and sensing apparatus 125. In case the processor 230 already computed the Factor for both 115 and 125, or at least to one of them. The processor 230 then uses the delta between the previous scalar value of each sensing unit, multiply it by the calculated Factor and compute the change in the power consumption per each appliance.

The processor 230 may also save data that describe the power consumption behavior per electrical appliance. This information is useful in cases where more than one sensing apparatus sends a HOLO indication at the same time. For example, when the central unit 200 receives data related to an electrical appliance like Iron that consumes 1800 watt when it warms up, returns to zero consumption after reaching the working temperature, and so on. If the sensing apparatus related to the Iron sends a HIGH indication at the same time as another sensing apparatus sends indication, the processor 230 estimates that the Iron again consumes 1800 watt. The processor 230 can compute the updated power consumption of the second electrical appliance.

The central unit 200 may also comprise a pattern unit 225. The pattern unit 225 receives power consumption indications or other data from the processor 230 or from another entity such as the power supplier or the manufacturer of the electrical appliance. The pattern unit 225 further stores the previous power consumption profiles of a specific electrical appliance. The pattern unit 225 may provide a list of the most consuming appliances, or the days with the highest power consumption. The pattern unit 225 may also generate reports to the user of the electrical appliances or to the electrical power supplier. The pattern unit 225 may associate data received by the receiving unit to a specific electrical appliance. For example, when the data from the sensing apparatus 235 lacks association to a specific electrical appliance, the pattern unit 225 may compare the data related to the power consumption of the electrical appliance with previously stored power consumptions and power consumption profiles. The pattern unit 225 may then determine or estimate the electrical appliance related to the power consumption data received by the receiving unit 220.

The central unit 200 may further comprise a malfunction detection unit 240. The malfunction detection unit 240 receives the estimated power consumption of electrical appliances from the processor 230. The malfunction detection unit 240 further receives consumption history from the pattern unit 225, for example, the time in the day in which the electrical appliance is ON, the averaged power consumption in weekends and the like. The malfunction detection unit 240 provides estimations as to whether one or more electrical appliances operate in a manner significantly different from the manner or profile stored in the central unit 200, which may point to a problem in the electrical appliance. For example, when the receiving unit 220 receives indication that the power consumption of a refrigerator is higher than usual for a certain period, perhaps the door is not closed properly. Similarly, when the processor 230 or the pattern unit 225 associate power consumption of an electrical appliance for a period of time double that the standard use, the malfunction detection unit may send a message to the user that the electrical appliance may operate unintentionally. For example, a water heater that operates more than 4 hours. The malfunction detection unit 240 may also generate a message to the user or to a receiver in an electrical appliance to change a property in the operation of the electrical appliance, for example a command to change the temperature in the air-conditioner to reduce power consumption.

The central unit 200 may also comprise a financial unit 255 to convert power consumption into a financial value, according to a predefined set of rules. The financial unit 255 may then generate a financial report to the user or the owner of electrical appliances, and suggest alternative consumption programs. For example, the financial unit 255 may provide specific times in a day for each electrical appliance to operate. The financial unit 255 may be connected to electrical appliances to generate and send a command to said electrical appliances. Such command or message may be reducing power consumption, changing manner of use, postponing a task operated by the electrical appliance such as washing dishes and the like. The financial unit 255 may provide the cost in money and/or CO₂ emission per use of electrical appliance.

The central unit 200 may further comprise a display device 205. Such display device 205 may display power consumption graphs, messages to the user of the electrical appliances, alerts and the like. The display device 205 can be a separate device that is connected to the central unit 200.

The central unit 200 may be located in a location adjacent to the electrical appliances or in a remote location and connected to the sensing apparatus 210 and the power meter using communication environment such as the internet. One central unit such as central unit 200 may provide measurement and analysis services to more than one user, for example more than one apartment or office. The central unit 200 may alternatively reside or be connected to the electrical power company servers.

The central unit 200 may also comprise a transmitter 280 for transmitting data to external entities. Such external entities may be the electrical appliances, the user's phone or email address, the power company and the like. The external entities may also be the sensing apparatus 215 and the display device 205. The data may comprise messages or commands. For example, command to the electrical appliance to change or delay operation. A message to the user may contain reports as noted above.

The central unit 200 may also contain a history storage 270 for containing the history of operations of the electrical appliances, the power consumption, previous reports and the like. In some cases, one history storage 270 may contain data related to more than one power meter or to more than one apartment or office.

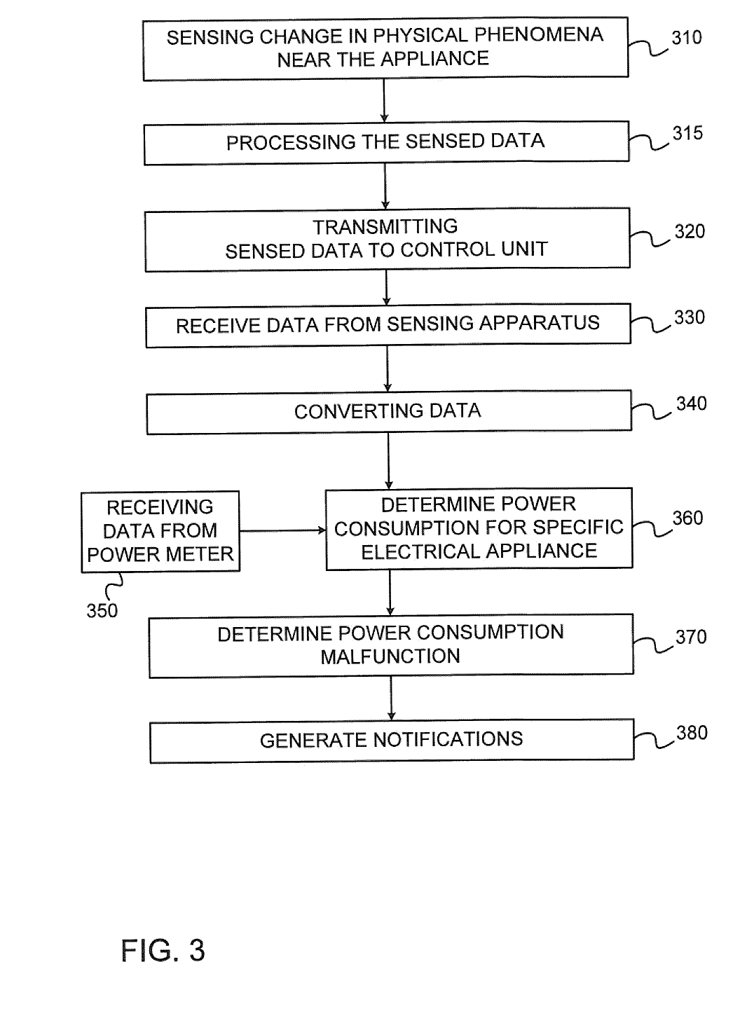

FIG. 3 shows a flow of measuring power consumption of electrical appliances, according to some exemplary embodiments of the disclosed subject matter. Step 310 provides for sensing change in a physical phenomena measured near the electrical appliance or near a power cable. Such physical phenomena may be light, magnetic field amplitude, noise, rounds per minute of an engine and the like. When sensing magnetic field, the magnetic sensor comprises a coil. The coil may be in a cylindrical shape and may be clamped to a power cable leading power to the electrical appliance.

In step 315, the sensing apparatus processes the sensed data. For example, performs mathematical operations such as averaging the previous samples as sensed by the sensing module. Another example is analog to digital conversion of the sensed information into a scalar that is sent to the central unit. In some exemplary embodiments, the sensing apparatus further runs a command or a set of rules on the sensed data in order to convert the sensed data into a scalar, which is a scalar transmitted to the processing unit to provides estimation as to the real power consumption of the electrical appliance.

In step 320, the sensed data is transmitted from the sensing apparatus to the central unit. Transmission from the sensing apparatus may be wired, wireless or a combination thereof, as desired by a person skilled in the art. In some exemplary embodiments of the disclosed subject matter, the transmitted data contains HOLO representation. In such case, the sensing apparatus sends indication as to whether the electrical appliance is On, Off, and whether the power consumption increased or decreased. The indication discloses whether the electrical appliance operates, does not operate, and whether the power consumption increases (High) or decreases (Low). The indication may also contain one or more scalars, as noted above.

In step 330, the processing unit receives data from the sensing apparatus. Such data may be HOLO, scalar, or any other data that is a function of data sensed from near the electrical appliance. The received data may contain time stamp, ID related to the electrical appliance, operation function, sensing apparatus type and the like.

In step 340, the processing unit converts the data received from the sensing apparatus. Such conversion may be performed in case the data required by the processing unit for performing analysis is different from the data provided by the sensing apparatus. Alternatively, the amount of data provided by the sensing apparatus is insufficient and requires additions. For example, converting the scalar value into a value in a predefined range to fit software or hardware modules in the processing unit that measure and analyze power consumption of electrical appliances.

In step 350, the processing unit receives data from a power meter associated with the electrical appliances sensed by the sensing apparatus. In some embodiments, step 350 is performed simultaneously to other steps, such as step 330. Such power meter measures the sum of electrical power in a predetermined period and provides that sum to the processing unit, in addition to the time in which it was measured.

In step 360, the processing unit determines power consumption of specific electrical appliances. In some cases, when the sensing apparatus associated with one electrical appliance transmits an ON message and the power meter transmits an increase in the total power consumption, the power consumption of the specific electrical appliance is a function of the increase measured by the power meter. In some cases, receiving a High message or a Low message from the sensing apparatus provides that there was a change in the physical phenomena sensed by the sensing apparatus associated with the electrical appliance. In some cases, when the sensing apparatus associated with one electrical appliance transmits a scalar, the processing unit may calibrate the received data according to previously received data, previous estimations, a predefined set of rules and the like. As such, the processing unit calculates the updated power consumption of the EAs and updates the pattern storage. Such storage device may be for example the pattern storage or another storage in the central unit. The receiving unit of the central unit may receive two or more indications of power consumption at the same time. The processor may determine the change in the power consumption per appliance

In step 370, the processing unit determines power consumption malfunction or abnormal behavior of electrical appliances sensed by sensing apparatuses that send data to the processing unit. Malfunction may be determined in various cases. For example, in case an electrical appliance operates continuously longer than ever sensed before or at different times in the day. In case a dishwasher operates at 3 A.M., the processing unit may determine that there is something unusual. In some other cases, when determining malfunction may be done when the power consumption of an electrical appliance is higher than ever sensed before. A sensing apparatus associated with a washing machine may send indication that the washing machine consumes double than regular. As a result, the processing unit may determine power consumption malfunction.

In step 380, the processing unit generates a notification concerning the power consumption of one or more electrical appliances. For example, the notification provides that when a specific electrical appliance operates at night it consumes 40 percent less money than in the evening. Such notifications may be sent from a power company to the user or owner of the electrical appliance. Some notifications may concern financial aspects, as noted above.

FIG. 4 shows the connection of the sensing apparatus to the power cable in the exemplary embodiment where the sensing apparatus measures the magnetic field adjacent to the power line connected to the associate electrical appliance. A standard power cable 420 contains two electrical conductors 410, 412, via which power runs to the electrical appliance. The magnetic field surrounding the entire power cable 420 is zero or close to zero, since the magnetic fields of both electrical conductors 410, 412 balance each other. A measuring unit 430 is positioned adjacent to the power cable 420. The measuring unit 430 contains a coil 435, a LED 440 and a button 450. The coil 435 provides for sensing the magnetic field in some point near the power cable, for example in the closest point to the electrical conductor 410 and farthest point relative to the electrical conductor 412. In such exemplary location, the magnetic fields generated by the electrical conductors do not balance each other and the coil can measure differences in the power consumption of the electrical appliance from outside the power cable 420. As a result, the sensing apparatus 135 of FIG. 1 enables measuring power consumption by positioning a measuring unit on the power cable 420 without opening the power cable 420 to detect the magnetic field of the electrical conductors 410, 412. In some cases, the measuring unit 430 comprises two or more coils positioned in various locations adjacent to the power cable 420 where the magnetic fields of both electrical conductors 410, 412 do not balance each other.

The LED 440 is used to provide indication as to the position of the measuring unit, especially the position of the coil 435. The magnetic field magnitude sensed by the coil 435 is one of the parameters used to detect whether the position of the coil 435 is sufficient. The LED also indicates whether it is recommended to activate the EA at this point of time, indicate low battery power, indicate internal problem inside the sensing apparatus and the like. The button 450 may be used to indicate beginning of the installation procedure. It can also be used for testing and to reset the sensor.

One technical effect of the disclosed subject matter is the ability to detect power consumption of electrical appliances non-intrusively, especially during installation and operation of the system. Another technical effect is the ability to detect power consumption of specific electrical appliances without requiring modifications of the same. Another technical effect is the ability to create power consumption reports according to the data sensed from the vicinity of the electrical appliances. Another technical effect is the ability to sense power consumption without the need to connect to a specific socket or electrical element. Another technical effect is the ability to install and reinstall sensing apparatus unrelated to the electrical environment.

While the disclosure has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings without departing from the essential scope thereof. Therefore, it is intended that the disclosed subject matter not be limited to the particular embodiment disclosed as the best mode contemplated for carrying out this invention, but only by the claims that follow.

1. A system for measuring power consumption of an electrical appliance, the system comprises:
a sensing module for sensing physical phenomenon related to the power consumption of the electrical appliance;
said sensing module is located externally to the electrical appliance;
a transmitter for transmitting information related to the power consumption of the electrical appliance, said information represents the physical phenomenon sensed by the sensing module;
a power device.

2. The system of claim 1, wherein the physical phenomenon sensed by the sensing module provides indication on whether the electrical appliance is ON or OFF.

3. The system of claim 1, wherein the physical phenomenon sensed by the sensing module provides an indication on whether the power consumption of the electrical appliance increased or decreased.

4. The system of claim 3, wherein the indication comprises one or more scalar values indicating change in the magnitude of the sensed information.

5. The system of claim 3, wherein the indication comprises one or more scalar values indicating the magnitude of the sensed information.

6. The system of claim 1, wherein the sensing module senses a magnetic field adjacent and external to the power cable transferring power to the electrical appliance.

7. The system of claim 1, further comprises a processing unit for determining the information transmitted by the transmitter according to the sensed physical phenomenon.

8. The system of claim 1, wherein the sensing module enables sensing the physical phenomenon without opening the power cable or connecting an intermediate apparatus located between the electrical plug and the power outlet associated with the electrical appliance.

9. The system of claim 1, wherein the sensing module enables sensing the physical phenomenon without inducing a predefined current into an electrical conductor within the power cable.

10. The system of claim 1, wherein the physical phenomenon is selected from a group consisting of heat, light, noise, motion, rotation speed or a combination thereof.

11. The system of claim 1, further comprises a clamping device for attaching the sensing module to the power cable transferring power to the electrical appliance, said power cable contains two or more electrical conductors, wherein the sensing module senses the magnetic field magnitude externally to the power cable,
and wherein the sensing module is positioned in a location in which the magnetic field magnitudes of the two or more electrical conductors do not balance each other.

12. A system for determining power consumption of an electrical appliance, the system comprising:
a first receiving unit for receiving information from a sensing module located externally to the electrical appliance;
a second receiving unit for receiving information from a power meter that stores power consumption of a plurality of electrical appliances, at least one of the plurality of electrical appliances is associated with a sensing module that sends information representing the physical phenomenon sensed by the sensing module and transmitted to the first receiving device;
a processor for determining the power consumption of the electrical appliance as a function of the information received at the first receiving unit and at the second receiving unit.

13. The system of claim 12, further comprises a pattern unit for storing power consumption of electrical appliances in specific times and determine the pattern of the power consumption of specific electrical appliances in specific time frames.

14. The system of claim 12, further comprises a malfunction/abnormal behavior detection unit that compares the power consumption determined by the processor and the pattern stored in the pattern unit to determine whether the consumption is valid or invalid.

15. A method of measuring power consumption of electrical appliances, the method comprising:
receiving information from a power meter that stores power consumption of a plurality of electrical appliances;
receiving an indication from a sensing apparatus associated with an electrical appliance of the plurality of electrical appliances, said indication provides information representing physical phenomenon sensed by a sensing module located externally to the electrical appliance and externally to the power cable transferring power to the electrical appliance;
determining the power consumption of the electrical appliance as a function of the information received from the power meter and the information received from the sensing apparatus.

16. The method according to claim 15, wherein the indication is limited to whether the electrical appliance is ON or OFF and whether the power consumption of the electrical appliance increased or decreased.

17. The method according to claim 15, wherein the indication is a scalar, which is a function of the data, sensed externally to the power cable and externally to the electrical appliance.

18. The method according to claim 15, further comprises a step of calculating a factor between the scalar received from a specific electrical appliance and the difference in power consumption of the same electrical appliance.

19. The method according to claim 18, further comprises a step of determining the power consumption of the electrical appliance using the factor.
